(19) United States
(12) Patent Application Publication
(10) Pub. No.: US 2005/0002613 A1
(43) Pub. Date: Jan. 6, 2005

(54) LED device

(76) Inventors: Michael Rehberger, Kinnelon, NJ (US); Robert Sagebiel, Goveville, NJ (US); Michael Cazzola, Toms River, NJ (US)

Correspondence Address: OSTROLENK, FABER, GERB & SOFFEN, LLP, 1180 Avenue of the Americas, New York, NY, 10036-8403, US

(21) Appl. No.: 10/722,927

(22) Filed: Nov. 25, 2003

Related U.S. Application Data
(60) Provisional application No. 60/429,238, filed on Nov. 25, 2002.

(51) Int. Cl. G02B 6/12; H01L 27/15; H01L 33/00; G02B 6/30

(52) U.S. Cl. 385/49; 385/14; 257/82; 257/81; 257/99; 398/200

(57) ABSTRACT

An LED device including an LED and an optical transmitter both disposed lateral to one another on a common circuit board, the optical transmitter including a light input surface arranged to receive light from the LED.

### RELATED APPLICATION

The application is based on and claims benefit of U.S. Provisional Application No. 60/429,238, filed on Nov. 25, 2002, entitled SMT LIGHT PIPE, to which a claim of priority is hereby made.

### FIELD OF THE INVENTION

The present invention relates to surface mounted optical devices and a method of manufacturing the same.

### BACKGROUND OF THE INVENTION

Light emitting diodes are well know semiconductor devices. Similar to all semiconductor devices light emitting diodes are packaged for use in practical circuits.

A conventional light emitting diode package (LED) includes an LED die, which may be bonded onto a circuit board, and a lens element, which is transfer molded over the LED die.

According to a conventional technique an LED die is bonded to a circuit board, and then protected by a transparent protective covering which is applied by, for example, a transfer molding technique. Because the protective covering does not have a suitable lensing capability to provide directional or optically controlled light output from the LED die a separate optical component is provided to receive the light output of the LED to act as a waveguide for the light and direct the light toward a desired location.

According to the prior art, the separate optical component is typically assembled manually after the LED is attached to the circuit board in order to avoid exposing the separate optical component to the high temperatures of processing, for example, the solder reflow temperature, so that damage to the separate optical component may be prevented. Thus, the prior art device and the prior art technique for assembling the device require one processing step for assembling the LED onto a circuit board and a second separate step for assembling the optical component.

It is desirable to have a device which can be assembled without the need for a manual step.

### SUMMARY OF THE INVENTION

It is an object of the present invention to provide an LED device and a method for manufacturing an LED device which does not include a manual assembly step.

Another object of the present invention is to provide an optical transmitter which can be combined with an LED to form an LED device in a simplified manufacturing process.

An LED device according to the present invention includes an LED mounted on a circuit board, and an optical transmitter having a light input surface and a light output surface, the light input surface being arranged to receive light from the light radiating surface of the LED.

According to an aspect of the present invention the optical transmitter is positioned lateral to the LED on the circuit board and is attached to the circuit board by an adhesive.

According to a preferred embodiment of the present invention the adhesive used for attaching the optical transmitter to the circuit board is the same material as the adhesive used for attaching the LED to the circuit board to simplify manufacturing. Solders or conductive epoxies are examples of preferred adhesives.

An optical transmitter according to the present invention includes a base which is formed from a substance that can be attached to a circuit board. Metallic substances that can be attached to a circuit board using adhesives such as solder are preferred.

The base in the preferred embodiment of the present invention is attached to an optical element devised to receive light from the LED. The optical element includes an optical conduit that has a light output surface, and an optical coupler coupled to the optical conduit which has a light input surface to receive light from the LED, and an optically transparent body which can transmit light to the light conduit so that the light can escape from the light output surface.

In a method for manufacturing an LED device according to the present invention a circuit board having solder pads is provided, adhesive is applied to the solder pads, an optical transmitter according to the present invention and an LED are disposed on the adhesives, and the adhesive is activated. In the preferred embodiment, the adhesive is solder. The solder is activated by being reflown at its reflow temperature.

Other features and advantages of the present invention will become apparent from the following description of the invention which refers to the accompanying drawings.

### BRIEF DESCRIPTION OF THE DRAWINGS

FIG. 1 shows a perspective view of an optical transmitter according to the first embodiment of the present invention.

FIG. 2 shows a side plan view of an LED device according to the present invention.

FIG. 3 shows a front plan view of an LED device according to the present invention viewed in the direction of arrows 2-2 in FIG. 2.

FIG. 4 shows a side plan view of an alternate LED device according to the present invention.

FIG. 5 shows a portion of a circuit board that may be used in the alternate LED device according to the present invention.

FIG. 6 shows a front plan view of the alternate LED device according to the present invention viewed in the direction of the arrows 6-6 in FIG. 4.

FIG. 7 shows a front plan view of an LED device including an optical transmitter according to the second embodiment of the present invention.

FIG. 8 shows a top plan view of a portion of a carrier tape for transporting optical transmitters according to the present invention in a manufacturing line.

FIG. 9 is a cross-sectional view of the carrier tape of FIG. 8 along line 9-9 viewed in the direction of the arrows.

### DETAILED DESCRIPTION OF THE FIGURES

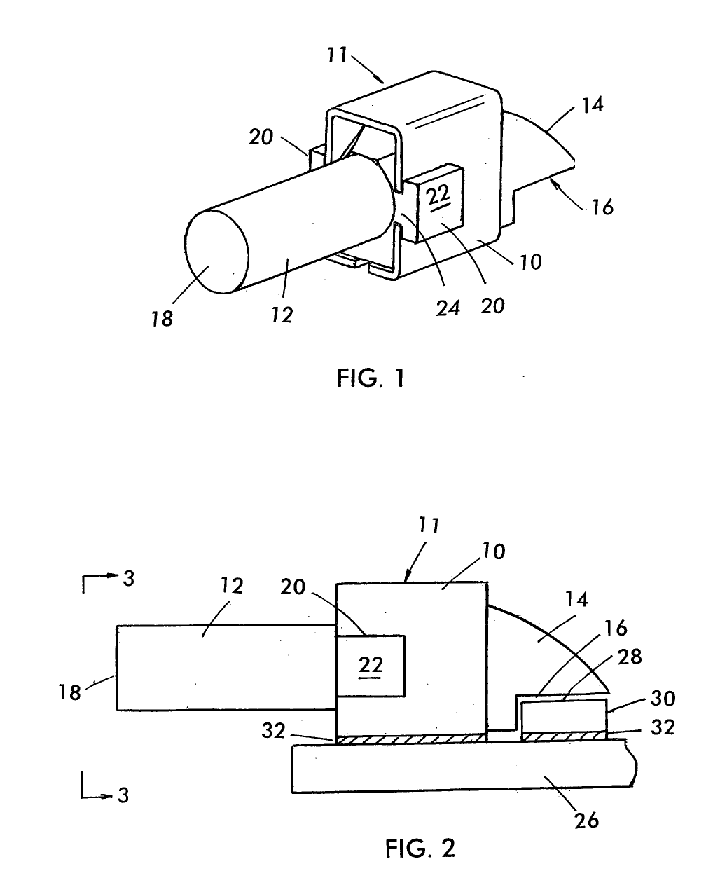

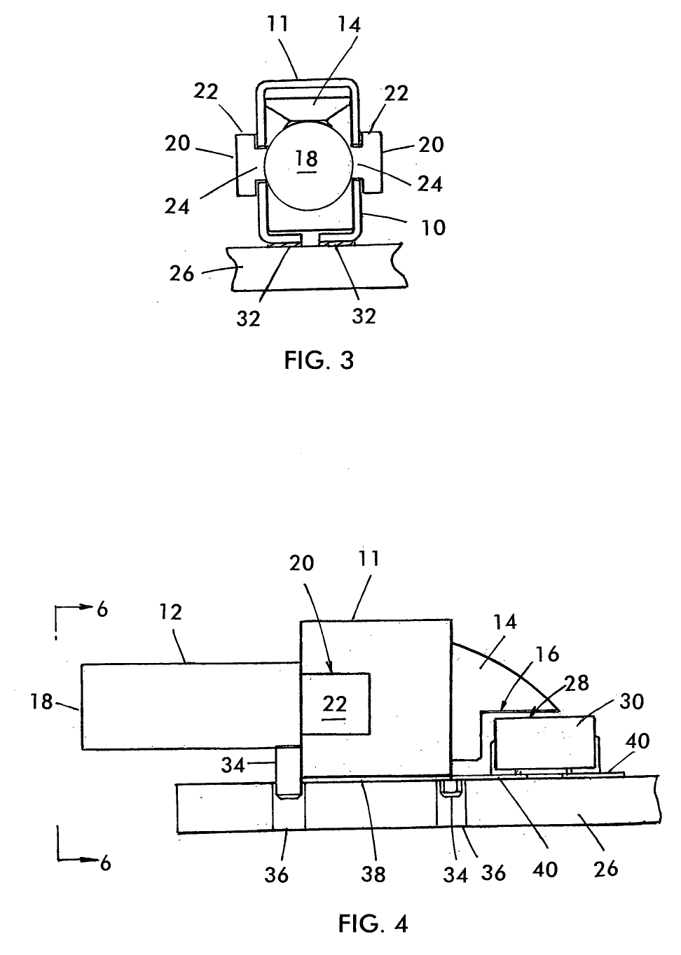

Referring to FIG. 1, a surface mounted optical transmitter according to the first embodiment of the present invention includes base 10, and light conduit 12 which is optically coupled to optical coupler 14. Optical coupler 14 has an optically transparent body and includes light input surface 16 which is capable of receiving light from a light source so that light may be transmitted through the body of optical coupler 14 to optical conduit 12. Optical conduit 12 includes light output surface 18 from which light can escape. In the preferred embodiment of the present invention, optical conduit 12 is an injection molded waveguide, and optical coupler 14 is a set of internally reflective contours. Preferably, optical conduit 12 is integral with optical coupler 14, and may be formed with the same as a unitary body. For example, optical conduit 12 and optical coupler 14 may be formed as a single piece from an optically transparent high temperature thermoplastic. An example of a suitable thermoplastic material is methyl pentene copolymer, sold, for example, by Matsui Chemicals under the mark TPX. Optical conduit 12 may be cylindrical, or any other desirable shape.

Base 10 according to the present invention is of a substance that can be attached to a circuit board. Preferably, a metallic substance having the capability of being attached to a circuit board by a conventionally known adhesives such as solder is used to form base 10.

According to the first embodiment of the present invention, base 10 is formed in the form of a sleeve which surrounds optical coupler 14. The sleeve configuration includes a relatively flat top surface 11 which can be used by an ordinary pick and place apparatus to lift and transport an optical transmitter according to the present invention. Also, a metallic sleeve may act as a reflector to optimize light throughput through optical coupler 14 and/or reduce the escape of light from the sides of optical coupler 14 and thus reduce cross-talk. Alternatively, a flat landing may be formed into optical coupler to serve the same function as top surface 11.

To secure optical coupler 14 to base 10, anchors 20 are provided on opposing vertical sides of optical coupler 14. Each anchor 20 includes a head portion 22, and neck portion 24. Neck portion 24 of each anchor 20 is received in a corresponding slot in base 10. As a result, lateral movement of optical coupler 14 inside base 10 is restricted.

Referring now to FIG. 2, in a light emitting diode (LED) device according to the present invention an optical transmitter according to the present invention is preferably assembled onto circuit board 26 such that light input surface 16 is opposed to the light radiating surface 28 of LED 30, which serves as a light source. In the preferred embodiment of the present invention, an optical transmitter according to the present invention is attached to circuit board 26 in a position that is lateral to LED 30. Also, in the preferred embodiment of the present invention LED 30 and base 10 are attached to circuit board 26 using solder 32 as an adhesive.

Solder is preferred in that it can serve as a conductive substance for electrically connecting LED 30 to a respective conductive pad on circuit board 26, as well as an adhesive for attaching base 10 to a respective solder pad on circuit board 26. Thus, solder can be applied in one step to the conductive pad that is to receive LED 30 and the solder pad that is to received base 10, and reflown in another step once LED 30 and base 10 are positioned in place. As a result, when solder is used manufacturing can be simplified.

It should be noted that the combination of an LED and an optical transmitter according to the present invention is only one embodiment of the invention. Other light sources, for example, a fiber optic light source can also be combined with an optical transmitter according to the present invention without departing from the spirit of the invention.

Referring now to FIG. 4, an optical transmitter according to the first embodiment of the present invention may include alignment pins 34 which are receivable in corresponding alignment holes 36 in circuit board 26. The alignment pins 34 are provided to ensure that light input surface 16 properly registers with light radiating surface 28 of LED 30 once the optical transmitter is positioned on circuit board 26.

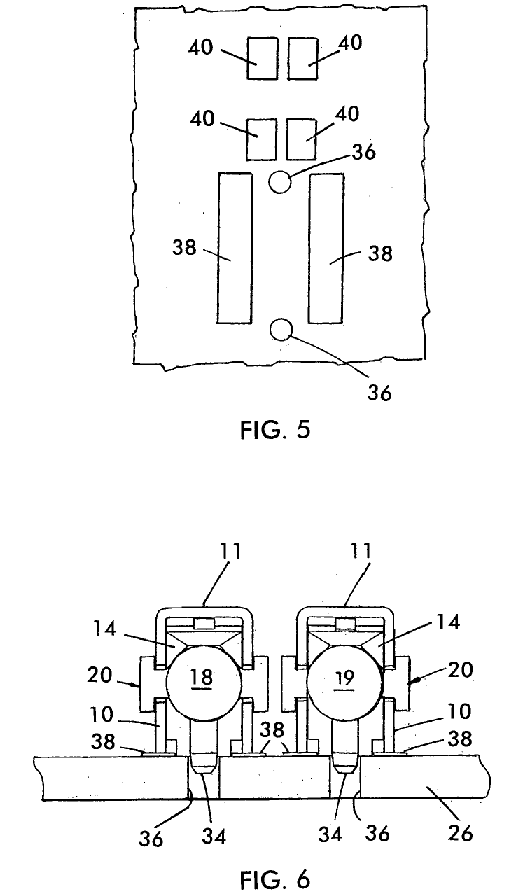

Referring now to FIG. 5, circuit board 26 as used in an LED device according to the present invention includes solder pads 38 which receive portions of base 10, and conductive pads 40 to receive LED 30 in a position lateral to the optical transmitter. Solder or some other suitable adhesive may be used for attaching base 10 of an optical transmitter according to the present invention to solder pads 38 on circuit board 26.

Referring now to FIG. 6, the present invention is not restricted to one optical transmitter but circuit board 26 may include more than one set of solder pads 38 for a plurality of optical transmitters and a respective number of LEDs 30 each associated with a respective optical transmitter.

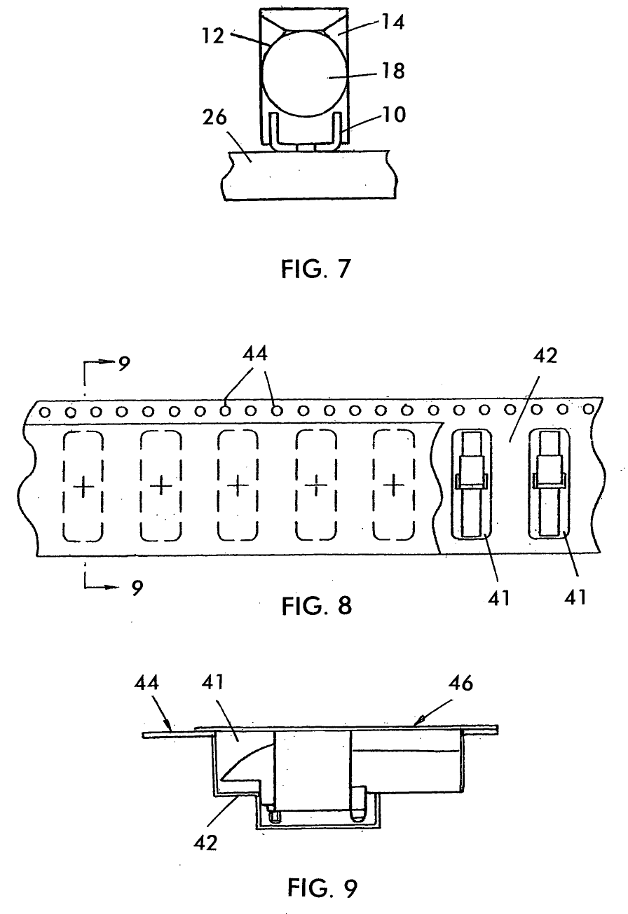

Referring now to FIG. 7, an optical transmitter according to a second embodiment of the present invention includes base 10 which is received and embedded in the body of optical coupler 14 instead of surrounding the same as is the case in the first embodiment of the present invention. Base 10 in the second embodiment of the present invention is also preferably formed from a metallic substance and is preferably attached to circuit board 26 to form an LED device in the manner described above.

According to one aspect of the present invention, an optical transmitter according to the present invention may be attached to a circuit board alongside an LED at the same time the LED is attached to the circuit. As a result an LED device may be obtained through a simplified manufacturing process.

For example, as shown by FIG. 8, a plurality of optical transmitters according to the present invention are disposed inside compartments 41 in carrier tape 42. Carrier tape 42 may be advanced in a manufacturing line by a sprocket mechanism (not shown) that engages sprocket holes 44 on carrier tape 42. A continuous cover tape 46 preferably covers compartments 41 and thus encloses the optical transmitters therein.

During the manufacturing of an LED device according to the present invention, cover tape 46 is first removed thereby providing access to an optical transmitter contained within compartment 41. FIG. 8 shows a portion of carrier tape 41 in which a portion of cover tape 46 is removed for illustration purposes. Using, for example, a pick and place apparatus, an optical transmitter is lifted out of its compartment 41 in carrier tape 42. Note, preferably, the pick and place machine will pick up an optical transmitter by engaging surface 11 at the top portion of base 10 (if a sleeve is used).

Next, the optical transmitter is placed atop solder pads 38 (see FIG. 5) of a circuit board 26 (or an equivalent structure). It should be noted that prior to the placement of the optical transmitter an adhesive is either applied to the bottom of base 10 or solder pads 38 which receive base 10. Also, preferably, before the placement of the optical transmitter LED 30 is placed on conductive pads 40 (see FIG. 5) on circuit board 26 with an appropriate adhesive interposed between LED 30 and conductive pads 40.

After the optical transmitter is placed, the adhesive between LED 30 and conductive pads 40, and the adhesive between base 10 and solder pads 38 are activated to form an LED device according to the present invention.

In the preferred embodiment of the present invention a conventional solder may be used as the adhesive for attaching the optical transmitter according to the present invention and LED 30. For example, a conventional lead/tin solder paste may be used. A conventional lead/tin solder paste may be activated by application of heat so that it may be reflown to attach base 10 and LED 30 to their respective positions on circuit board 26. A typical reflow temperature may be 220° C. Thus, in the preferred embodiment of the present invention base 10 must be formed of a material that can withstand the reflow temperature if solder is used. As noted before solder is preferred in that it may be deposited in one step before LED 30 and the optical transmitter are positioned in place on circuit board 26, and then reflown in another step to attach the same to circuit board 26, thereby simplifying the manufacturing of an LED device according to the present invention.

Alternatively, some form of thermally activated epoxy may be used instead of solder. For example, a silver loaded epoxy may be used for attaching base 10 of an optical transmitter according to the present invention and LED 30 to circuit board 26.

Although it is preferred to use the same adhesive for attaching base 10 and LED 30, it is also possible to use different adhesives so long as the material for base 10 is selected to withstand manufacturing temperatures after the optical transmitter is placed on circuit board 26.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

1. An optical transmitter comprising:
an optical conduit having a light output surface;
an optical coupler having a light input surface that is adapted to receive light from a light source and an optically transparent body that is capable of transmitting said light from said light source to said light conduit whereby light received from said light source may be transmitted to said light output surface; and
a base adapted for attachment to a circuit board.

2. An optical transmitter according to claim 1, wherein said light source is a light emitting diode.

3. An optical transmitter according to claim 2, wherein said base is a sleeve that is disposed around at least a portion of said optical coupler.

4. An optical transmitter according to claim 1, wherein said optical conduit is a waveguide.

5. An optical transmitter according to claim 1, wherein said optically transparent body is integral with said light conduit.

6. An optical transmitter according to claim 1, wherein said base is embedded in said optical coupler.

7. An optical transmitter according to claim 1, wherein said base is comprised of a metallic substance.

8. An optical transmitter according to claim 1, wherein said base can withstand at least a reflow temperature of a conventional solder.

9. An optical transmitter according to claim 1, wherein said base includes a portion adapted to be receivable by a conventional pick and place apparatus.

10. A light emitting diode device comprising:
a circuit board;
a light emitting diode disposed on said circuit board;
an optical transmitter, said optical transmitter being arranged on said circuit board lateral to said light emitting diode and including a light input surface arranged to receive light from said light emitting diode; and
a base attached to said light transmitter and said circuit board, whereby said light transmitter is coupled to said circuit board.

11. A light emitting diode device according to claim 10, wherein said optical transmitter includes a light conduit and a light coupling body, wherein said light input surface is on said light coupling body.

12. A light emitting diode device according to claim 10, wherein said base is comprised of a metallic substance.

13. A light emitting diode device according to claim 10, wherein said base and said light emitting diode are attached to said circuit board by solder.

14. A light emitting diode device according to claim 10, wherein said optical transmitter includes a waveguide integral with a set of optical internally reflective contours.

15. A light emitting diode device according to claim 10, wherein said light input surface is disposed over a light radiating surface of said light emitting diode.

16. A light emitting diode device according to claim 10, wherein said optical transmitter include a recess which receives a portion of said light emitting diode, said light input surface comprising a portion of said recess.

17. A method of manufacturing a light emitting diode device comprising:
providing a circuit board;
providing a light emitting diode;
disposing a first quantity of adhesive on a first portion of said circuit board and a second quantity of adhesive on a second portion of said circuit board;
placing said light emitting diode on said first quantity of adhesive;
providing a light transmitter having a light input surface and a base;
placing said light transmitter on said second quantity of adhesive such that said base is in contact with said second quantity of adhesive and said light input surface is arranged to receive light from said light emitting diode; and
activating at least said first quantity of adhesive.

18. A method according to claim 17, wherein said first quantity of adhesive and second quantity of adhesive are activated together.

19. A method according to claim 17, wherein said activating step is carried out by application of heat.

20. A method according to claim 17, wherein said first and said second adhesives are comprised of solder.

21. A method according to claim 17, wherein said first and said second adhesives are comprised of a conductive epoxy.

22. A method according to claim 17, wherein said base is comprised of a metallic substance.

23. A method according to claim 17, wherein said base is capable of withstanding at least said activation temperature of said first adhesive.

24. A method according to claim 17, wherein said first and said second adhesives are of the same material and have the same activation temperature.
